(19) United States
(12) Patent Application Publication
(10) Pub. No.: US 2026/0160844 A1
(43) Pub. Date: Jun. 11, 2026

(54) MAGNETIC RESONANCE IMAGING METHOD AND MAGNETIC RESONANCE IMAGING SYSTEM

(71) Applicant: GE Precision Healthcare LLC, Waukesha, WI (US)

(72) Inventors: Hui Wang, Beijing (CN); Xiaoli Zhao, Beijing (CN); Hanbei Zhang, Beijing (CN); Yongchuan Lai, Beijing (CN); Xiaocheng Wei, Beijing (CN)

(21) Appl. No.: 19/414,114

(22) Filed: Dec. 9, 2025

(30) Foreign Application Priority Data
Dec. 9, 2024 (CN) 202411803104.6

(51) Int. Cl. G01R 33/565; G01R 33/56; G01R 33/561

(52) U.S. Cl. CPC G01R 33/5659; G01R 33/5608; G01R 33/5617

(57) ABSTRACT

A magnetic resonance imaging method and system are provided. The method includes obtaining first image data using a first scan sequence, filtering the first image data to generate second image data, and estimating a radio-frequency field map based on the first and second image data. Scanned image data is then acquired using a second scan sequence and corrected using the estimated radio-frequency field map to obtain the corrected image data.

### CROSS REFERENCE TO RELATED APPLICATIONS

The present application claims priority and benefit of Chinese Patent Application No. 202411803104.6 filed on Dec. 9, 2024, which is incorporated herein by reference in its entirety.

### TECHNICAL FIELD

Embodiments of the present application relate to the technical field of medical devices, and in particular to a magnetic resonance imaging method and a magnetic resonance imaging system.

### BACKGROUND ART

In a magnetic resonance imaging apparatus, a subject to be examined is placed in an imaging space of a static magnetic field B₀ such that the proton spin within the subject to be examined is aligned to the direction of the static magnetic field so as to generate a magnetization vector. Then, a high-frequency magnetic field is formed by means of radio frequency pulses that transmit a resonance frequency, so that a magnetic resonance phenomenon occurs. The magnetic resonance phenomenon can cause the spinning direction of protons to be reversed to change the magnetization vector of the protons. When the spinning causes the protons to return to their initial state of the magnetization vector in the direction of the static magnetic field, a magnetic resonance signal is generated.

During magnetic resonance imaging, a radio-frequency field B₁ becomes increasingly non-uniform in response to an increase in the strength of the static magnetic field and an increase in the physique of a patient. Non-uniform distribution of B₁ may produce a dielectric shading in an image. The image may become non-uniform, and a change in tissue contrast may occur, or even the signal may be lost, resulting in a lack of sufficient image information to provide a reliable clinical diagnosis.

### SUMMARY OF THE INVENTION

In view of at least one of the foregoing problems, the embodiments of the present application provide a magnetic resonance imaging method and a magnetic resonance imaging system.

According to an aspect of the embodiments of the present application, a magnetic resonance imaging method is provided. The method comprises: obtaining first image data by using a first scan sequence; filtering the first image data to obtain second image data; estimating a radio-frequency field map based on the first image data and the second image data; and obtaining scanned image data by using a second scan sequence, and correcting the scanned image data based on the estimated radio-frequency field map to obtain the corrected scanned image data.

According to an aspect of the embodiments of the present application, a magnetic resonance imaging system is provided, the system comprises: a scanning unit; and a controller, configured to perform the magnetic resonance imaging method described in the previous aspect.

One of the beneficial effects of the embodiments of the present application lies in that, through: obtaining first image data by using a first scan sequence; filtering the first image data to obtain second image data; estimating a radio-frequency field map based on the first image data and the second image data, and correcting the scanned image data based on the estimated radio-frequency field map, the dielectric shading in the image can be reduced as much as possible, the missing signal and contrast in the image can be compensated for, the uniformity and consistency of the image can be enhanced, the quality of the image can be improved, and the confidence of diagnosis can be increased.

With reference to the following description and drawings, specific implementations of the embodiments of the present application are disclosed in detail, and the way in which the principles of the embodiments of the present application can be employed are illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to embodiments of the present application;

FIG. 2 is a schematic diagram of a magnetic resonance imaging method according to embodiments of the present application;

FIG. 3 is a schematic diagram of an implementation of operation 204 according to embodiments of the present application;

FIG. 4 is a schematic diagram of an implementation of operation 303 according to embodiments of the present application;

FIG. 5 is a schematic diagram of a magnetic resonance imaging method according to embodiments of the present application;

FIG. 6 is a schematic diagram of a second scan sequence according to embodiments of the present application;

FIG. 7 is a schematic diagram of an image correction process according to embodiments of the present application;

FIG. 8 is a schematic diagram of an image correction process according to embodiments of the present application;

FIG. 9 is a schematic diagram of scanned image data according to embodiments of the present application; and

FIG. 10 is a schematic diagram of corrected scanned image data according to embodiments of the present application.

### DETAILED DESCRIPTION OF EMBODIMENTS

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc. are used to distinguish between different elements in terms of appellation, but do not represent a spatial arrangement, a temporal order, or the like of these elements, and these elements should not be limited by these terms. The term “and/or” includes any one of and all combinations of one or more associated listed terms. The terms “include”, “comprise”, “have”, etc. refer to the presence of described features, elements, components, or assemblies, but do not exclude the presence or addition of one or more other features, elements, components, or assemblies.

In the embodiments of the present application, the singular forms “a” and “the”, etc., include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ” and the term “based on” should be construed as “based at least in part on . . . ”, unless otherwise specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

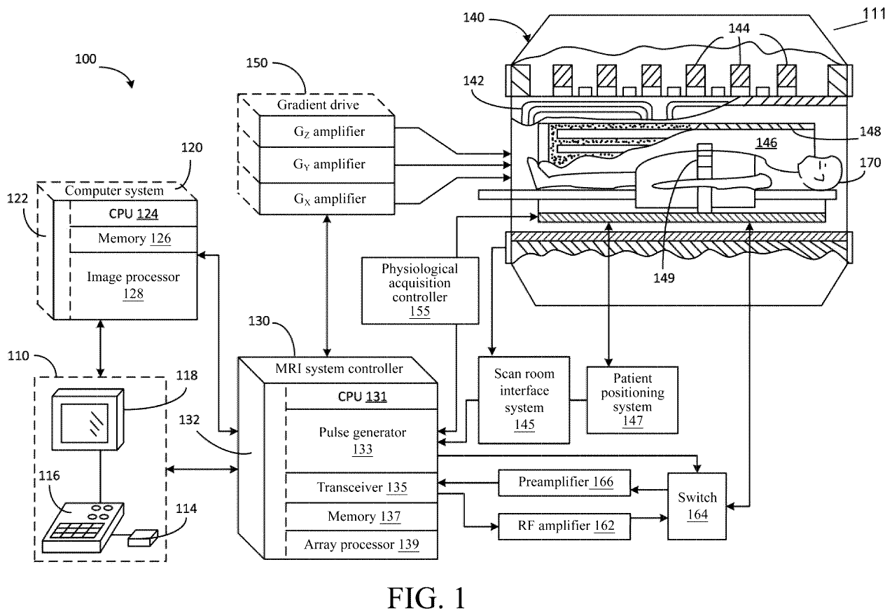

For ease of understanding, FIG. 1 shows a magnetic resonance imaging (MRI) system 100 according to some examples of the present invention.

The MRI system 100 includes a scanning unit 111. The scanning unit 111 is used to perform a magnetic resonance scan on a subject (for example, a human body) 170 to generate image data of a region of interest of the subject 170. The region of interest may be a predetermined anatomical site or anatomical tissue.

Operation of the MRI system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118. The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate MRI system controller 130.

The MRI system controller 130 includes a set of components that communicate with one another by means of an electrical and/or data connection module 132. The connection module 132 may employ a direct wired connection, a fiber optic connection, a wireless communication link, etc. The MRI system controller 130 may include a CPU 131, a sequential pulse generator 133 that communicates with the operator workstation 110, a transceiver (or an RF transceiver) 135, a memory 137, and an array processor 139. In some embodiments, the sequential pulse generator 133 may be integrated into a resonance assembly 140 of the scanning unit 111 of the MRI system 100. The MRI system controller 130 may receive a command from the operator workstation 110, and is coupled to the scanning unit 111, to indicate an MRI scan sequence that is to be performed during an MRI scan, so as to control the scanning unit 111 to execute the described magnetic resonance scan procedure. The MRI system controller 130 is further coupled to and communicates with a gradient driver system 150, and the gradient driver system is coupled to a gradient coil assembly 142 to generate a magnetic field gradient during the MRI scan.

The sequential pulse generator 133 may further receive data from a physiological acquisition controller 155. The physiological acquisition controller receives signals from a plurality of different sensors (for example, electrocardiogram (ECG) signals from electrodes attached to a patient), the sensors being connected to the subject or patient 170 undergoing the MRI scan. The sequential pulse generator 133 is coupled to and communicates with a scan room interface system 145, and the scan room interface system receives signals from various sensors associated with the state of the resonance assembly 140. The scan room interface system 145 is further coupled to and communicates with a patient positioning system 147, and the patient positioning system sends and receives signals to control the movement of a patient table to a desired position to perform the MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} gradient amplifiers excites a corresponding gradient coil in the gradient coil assembly 142, to generate a magnetic field gradient used to spatially encode an MR signal during an MRI scan. The gradient coil assembly 142 is disposed within the resonance assembly 140, the resonance assembly further includes a superconducting magnet having a superconducting coil 144, and during operation, the superconducting coil provides a static uniform longitudinal magnetic field B₀ that runs through a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146. The resonance assembly 140 may further include an RF surface coil 149, and the RF surface coil is used to image different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kₓ direction in k-space. The y direction may be referred to as a phase encoding direction or a k_{y} direction in the k-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses that are amplified by an RF amplifier 162 and provided to the RF body coil 148 by means of a transmit/receive switch (T/R switch) 164.

As described above, the RF body coil 148 and the RF surface coil 149 may be used to transmit an RF excitation pulse and/or receive obtained MR signals from the patient undergoing the MRI scan. MR signals emitted by excited nuclei in the patient of the MRI scan may be sensed and received by the RF body coil 148 or the RF surface coil 149 and sent back to a preamplifier 166 by means of the T/R switch 164. The T/R switch 164 may be controlled by a signal from the sequential pulse generator 133 to electrically connect, when in the transmit mode, the RF amplifier 162 to the RF body coil 148, and to connect, when in the receive mode, the preamplifier 166 to the RF body coil 148. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored as a raw k-space data array in the memory 137 for post-processing. A reconstructed magnetic resonance image may be obtained by transforming/processing the stored raw k-space data.

In some embodiments, the MR signals sensed and received by the RF body coil 148 or the RF surface coil 149 and amplified by the preamplifier 166 are demodulated, filtered and digitized in a receiving portion of the transceiver 135, and transmitted to the memory 137 in the MRI system controller 130. For each image that is to be reconstructed, the data is rearranged into separate k-space data arrays, each of the separate k-space data arrays is inputted into the array processor 139, and the array processor is operated to transform the data into an array of image data by means of a Fourier transform.

The array processor 139 uses a transform method, most commonly a Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 10 is intended for illustration. Suitable MRI systems may include more, fewer, and/or different components.

The MRI system controller 130 and the image processor 128 may separately or collectively include a computer processor and a storage medium. The storage medium records a predetermined data processing program that is to be executed by the computer processor. For example, the storage medium may store a program used to implement scanning (for example, a scan procedure and an imaging sequence), image reconstruction, image processing, etc. For example, the storage medium may store a program used to implement the magnetic resonance imaging method according to the examples of the present invention. The above storage medium may include, for example, a ROM, a floppy disk, a hard disk, an optical disk, a magneto-optical disk, a CD-ROM, or a non-volatile memory card.

The aforementioned “imaging sequence” (also referred to below as a scan sequence or a pulse sequence) is a combination of pulses that have specific amplitudes, widths, directions, and time sequences, and that are applied when a magnetic resonance imaging scan is performed. These pulses typically may include, for example, a radio-frequency pulse and a gradient pulse. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Typically, a plurality of scan sequences can be preset in the magnetic resonance system, so that the sequence suitable for clinical detection requirements can be selected. The clinical detection requirements may include, for example, an imaging site, an imaging function, an imaging effect, and the like.

Currently, a relatively simple method for reducing a dielectric shading comprises placing a dielectric pad between a part to be examined and a receiving coil. The displacement current in the dielectric pad can generate a localized radio-frequency field to enhance the B₁ field, and at the same time, the dielectric pad may render the shape of an imaged region to be closer to a spherical shape, thereby reducing the effect of non-uniformity of radio frequency inherent in an elliptical shape. However, the result of such a physical method is a very limited.

A method for reducing a dielectric shading in the field of algorithms is to apply an image-based post-processing filtering method, such as surface coil intensity correction, nonparametric, non-uniform intensity normalization (N3), and modified N3 bias correction (N4). However, these filtering methods cannot be used for quantitative data analysis, such as signal-to-noise ratio measurement. In order to solve this problem, some methods for performing correction based on pre-scanned image data have been subsequently proposed, said methods involve acquiring a low-resolution corrected scanned image so as to correct the non-uniform receiving coil before actual imaging. However, these methods cannot compensate for the non-uniformity of the radio-frequency field B₁, which can lead to spatial variation of the flip angle.

In order to address the non-uniformity of the radio-frequency field B₁, quite a number of methods for radio frequency shimming are currently proposed, such as redesigning of the radio frequency pulses, the radio frequency coil, and the radio frequency power, to equalize the distribution of the radio frequency flip angle. However, application of these methods may require modifying the current scanning procedure. Therefore, a method for predefining the radio-frequency field B₁ is subsequently proposed, which involves performing offline simulation of the body coil to acquire a radio-frequency field and pre-storing same in a magnetic resonance system, and correcting an image by using the pre-defined radio-frequency field. However, due to the complex interaction between the patient, the coil and the magnetic field, it is difficult to accurately simulate, at a higher field intensity (e.g., higher than 1.5 T), the B₁ field when the patient is located in a scanning chamber.

In view of at least one of the above problems, the present application proposes a method whereby the B₁ field (B₁ map) when a patient is located in a scanning chamber is estimated by using pre-scanned image data, and then the image data are corrected by means of the estimated B₁ field. The method can reduce a dielectric shading as much as possible, compensate for the missing signal and contrast in the image, enhance the uniformity and consistency of the image, improve the quality of the image, and increase the confidence of diagnosis.

Description is made below in conjunction with embodiments.

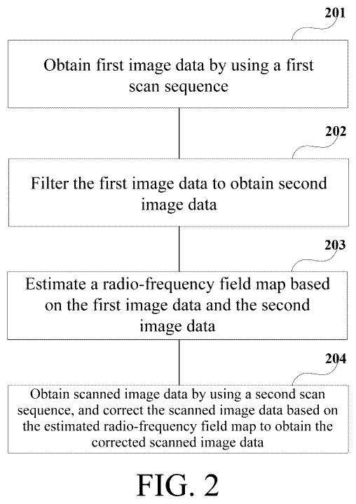

Embodiments of the present application provide a magnetic resonance imaging method. FIG. 2 is a schematic diagram of the magnetic resonance imaging method according to embodiments of the present application. As shown in FIG. 2, the method includes the following steps: 201, obtaining first image data using a first scan sequence; 202, filtering the first image data to obtain second image data; and 203, estimating a radio-frequency field map based on the first image data and the second image data. Then, in step 204, scanned image data is obtained using a second scan sequence and corrected based on the estimated radio-frequency field map to obtain the corrected scanned image data.

In some embodiments, a pre-scan (or termed as reference scan) needs to be performed before a formal diagnostic scan. When the pre-scan is performed, a subject under examination needs to enter a scanning chamber. After scan parameters are set, a scan sequence for the pre-scan is transmitted, and shimming data is determined and system settings are optimized (e.g., a center frequency is corrected, and a transmit gain, a receive gain, a correction phase etc. are determined). For example, in 201, when the pre-scan is performed, the subject may be scanned by using the first scan sequence, a magnetic resonance signal may be received by using a first coil, and first image data may be acquired based on the magnetic resonance signal, the first coil including a body coil. The first image data acquired by using the body coil may be low-resolution image data, and further may be a low-resolution proton density weighted image, which is generally considered to be relatively uniform. Here, only the body coil is taken as an example for illustration, but embodiments of the present application are not limited thereto. Other types of coils that obtain relatively uniform low-resolution proton density weighted images are also applicable to the present application.

In some embodiments, the first image data may be, for example, image data with a resolution of 64×64. This is only for illustration, and embodiments of the present application are not limited thereto. In some embodiments, the first scan sequence may include a spoiled gradient recalled echo (SPGR) sequence, namely, a gradient recalled echo sequence in which phase-disturbing combined frequency pulses are applied. The principle is that after a previous magnetic resonance signal acquisition, the phase of a proton group in a tissue is disturbed before a next radio frequency excitation pulse arrives, so as to accelerate dephasing of the proton group, thereby eliminating a residual transverse magnetization vector. The first image data collected based on the first scan sequence may be expressed by the following Formula (1):

$$SPGR = \frac{{M}_{0} sin α ( 1 - {e}^{- \frac{TR}{{T}_{1}}} ) {e}^{- \frac{TE}{{T}_{2}^{*}}}}{1 - cos α {e}^{- \frac{TR}{{T}_{1}}}} \approx \frac{{M}_{0} sin α ( 1 - {e}^{- \frac{TR}{{T}_{1}}} ) 1}{1 - 1 * {e}^{- \frac{TR}{{T}_{1}}}} \approx {M}_{0} sin α \approx ρα \qquad Formula ( 1 )$$

where, echo time

$$TE = 0.5 ms ≪ {T}_{2}^{*} , {e}^{- \frac{TE}{{T}_{2}^{*}}} \approx 1 ,$$

repetition time TR=1.5 ms<<T₁, actual transverse relaxation time is

$${T}_{2}^{*} ,$$

longitudinal relaxation time is T₁, flip angle α=1°, cos α≈1, M₀ represents macroscopic magnetization vector, ρ represents proton density, and ρ is positively correlated to M₀. Since the spoiled gradient recalled echo sequence can obtain a proton density-weighted image in a short time, relatively uniform first image data can be acquired by using the spoiled gradient recalled echo sequence. However, embodiments of the present application are not limited thereto. Other sequences that can quickly obtain a proton density-weighted image will also applicable to the present application, and will not be illustrated one by one here.

In some embodiments, the first image data may be approximately expressed as

$${S}_{body} ( \vec{r} ) = ρ ( \vec{r} ) {B}_{1}^{+} ( \vec{r} ) {B}_{1}^{-} ( \vec{r} ) , where {B}_{1}^{+} ( \vec{r} )$$

is the radio-frequency transmitting field of the first coil,

$${B}_{1}^{-} ( \vec{r} )$$

is the radio-frequency receiving field of the first coil, and \vec{r} represents spatial position. In embodiments of the present application, it is assumed that the radio-frequency field of the first coil

$${B}_{1} ( \vec{r} ) \approx {B}_{1}^{+} ( \vec{r} ) \approx {B}_{1}^{-} ( \vec{r} ) .$$

In 202, the first image data is homomorphically filtered to obtain second image data. The second image data can be approximately expressed as

$$HF ( {S}_{body} ( \vec{r} ) ) = HF ( ρ ( \vec{r} ) {B}_{1}^{+} ( \vec{r} ) {B}_{1}^{-} ( \vec{r} ) ) \approx ρ ( \vec{r} ) .$$

The uniformity of the first image data can be improved by the homomorphic filtering. The homomorphic filtering is merely an example of filtering, and embodiments of this application are not limited thereto. Other processes that can filter

$${B}_{1}^{+} ( \vec{r} ) {B}_{1}^{-} ( \vec{r} )$$

will also applicable to the present application.

In some embodiments, in 203, a radio-frequency field map

$${{B}_{1} ( \vec{r} )}^{estimate}$$

may be estimated based on the first image data and the second image data, wherein the radio-frequency field map

$${{B}_{1} ( \vec{r} )}^{estimate}$$

may be determined based on the ratio of the first image data to the second image data. The field map may be regarded as a spatial signal distribution value caused by the field intensity distribution of the radio-frequency field. For example, the radio-frequency field map

$${{B}_{1} ( \vec{r} )}^{estimate}$$

may be equal to the arithmetic square root of the ratio of the first image data to the second image data. That is, the radio-frequency field map

$${{B}_{1} ( \vec{r} )}^{estimate}$$

may be estimated by using the following Formula (2):

$${{B}_{1} ( \vec{r} )}^{estimate} \approx \sqrt{{B}_{1}^{+} ( \vec{r} ) {B}_{1}^{-} ( \vec{r} )} = \sqrt{\frac{{S}_{body} ( \vec{r} )}{HF ( {S}_{body} ( \vec{r} ) )}} \qquad Formula ( 2 )$$

It can be seen from the above embodiments that, in the pre-scan, the radio-frequency field map

$${{B}_{1} ( \vec{r} )}^{estimate}$$

of the first coil can be estimated based on the first image data acquired by the first scan sequence and the first coil.

In some embodiments, in 204, a formal scan is performed. The subject may be scanned using a second scan sequence, a magnetic resonance signal may be received using a second coil, and scanned image data may be acquired based on the magnetic resonance signal, the second coil comprising a surface coil (or, a local coil, which is specifically determined by an imaging site). The scanned image data are image data with a higher resolution than the first image data, for example, image data with a resolution of 512×512. This is only for illustration, and embodiments of the present application are not limited thereto.

In some embodiments, the second scan sequence includes a spin echo sequence. FIG. 6 is a schematic diagram of the second scan sequence according to embodiments of the present application, showing that within one repetition time, multiple radio-frequency refocusing pulses (e.g., 180°) are applied following a radio-frequency excitation pulse (e.g., 90°), and multiple echoes are collected. The multiple echoes are filled into multiple phase-encoding lines of a K-space to obtain scanned image data. Spin echoing typically uses radio-frequency refocusing pulses to refocus the phase of a proton group and gradually increase the transverse magnetization vector, such that echoes can be collected after the radio-frequency refocusing pulses end. Scan sequences adopting the spin echo mode include, but are not limited to, spin echo (SE) sequence, fast spin echo (FSE) sequence, single-shot (SS) FSE, etc., which will not be illustrated one by one here.

Described below is how to correct the scanned image data based on the radio-frequency field map

$${{B}_{1} ( \vec{r} )}^{estimate} .$$

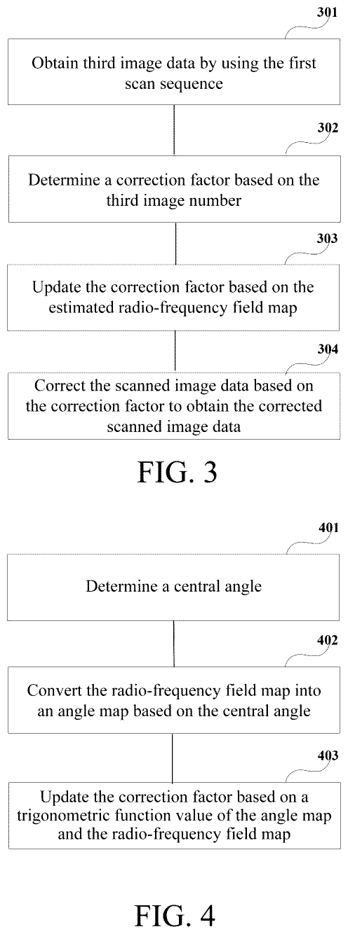

FIG. 3 is a schematic diagram of an implementation of operation 204 according to embodiments of the present application. As shown in FIG. 3, the operation 204 comprises: the following steps: 301, obtaining third image data using the first scan sequence; 302, determining a correction factor based on the third image data; and 303, updating the correction factor using the estimated radio-frequency field map. Finally, in step 304, the scanned image data is corrected based on the updated correction factor to obtain the corrected scanned image data.

In some embodiments, 301 may also be performed when performing the pre-scan. That is, when performing the pre-scan, the subject may be scanned using the first scan sequence, and as described above, the first image data are acquired using the first coil; in addition, a magnetic resonance signal is received using a second coil, and third image data are acquired based on the magnetic resonance signal. In embodiments of the present application, the order of acquiring the first image data and the third image data is not limited. For example, the first image data may be acquired first using the first coil, and then the third image data are acquired using the second coil; alternatively, the third image data may be acquired first using the second coil, and then the first image data are acquired using the first coil; alternatively, the third image data and the first image data may be acquired at the same time. These will not be illustrated one by one here. In addition, the first coil and the second coil need to be switched by a switch to receive the magnetic resonance signals, or need not be switched by a switch to receive the magnetic resonance signals. Embodiments of the present application are not limited thereto. The implementation of the second coil is as described above. That is, the second coil is used to obtain the third image data and the formal scanned image data. The third image data obtained by using the second coil may reflect the receiving sensitivity of the second coil. The third image data may be low-resolution image data, and further may be a low-resolution proton density-weighted image. For example, the third image data are an image having the same resolution as the first image data. That is, during the pre-scan, the first image data and the third image data may be acquired separately by using the same first scan sequence but using different receiving coils. The third image data may be expressed as

$${S}_{surface} ( \vec{r} ) .$$

In some embodiments, in 302, a correction factor may be determined based on the third image data and the first image data. For example, an initial correction factor P may be equal to the ratio of the first image data to the third image data, i.e.,

$$P = \frac{{S}_{body} ( \vec{r} )}{{S}_{surface} ( \vec{r} )} .$$

Alternatively, the correction factor may be determined based on the third image data and the second image data. For example, the initial correction factor P may be equal to the ratio of the second image data to the third image data, i.e.,

$$P = \frac{HF ( {S}_{body} ( \vec{r} ) )}{{S}_{surface} ( \vec{r} )} .$$

FIG. 4 is a schematic diagram of an implementation of operation 303 according to embodiments of the present application. As shown in FIG. 4, the operation 303 includes the following steps: 401, determining a central angle; and 402, converting the radio-frequency field map into an angle map based on the central angle. Then, in step 403, the correction factor is updated based on a trigonometric function value of the angle map and the radio-frequency field map.

In some embodiments, in 401, the central angle may be determined based on a flip angle of a radio-frequency transmitting pulse in the second scan sequence. For example, the central angle is equal to the flip angle of the radio-frequency transmitting pulse in the second scan sequence. For example, if the magnetic resonance image is obtained by executing an FSE sequence, and the flip angle is set to 90 degrees when the sequence is executed, then the central angle is determined to be 90 degrees.

In some embodiments, in 402, the radio-frequency field map

$${{B}_{1} ( \vec{r} )}^{estimate}$$

is converted to an angle map θ. For example, upon normalizing the radio-frequency field map

$${{B}_{1} ( \vec{r} )}^{estimate} ,$$

Bₘₐₚ is obtained. For example, normalization is achieved by

$${{B}_{1} ( \vec{r} )}^{estimate} / x = {B}_{map} ,$$

where x is the value where the excitation reaches a 90° flip of the central angle. The value of x may be an empirical value, which may be preset by a magnetic resonance system after being verified in many ways. For example, the value of x may range from 1.05 to 1.55, and embodiments of the present application are not limited thereto. The corresponding angle map θ can be obtained by multiplying the values at respective positions of the normalized map by

$$\frac{π}{2}$$

(90°).

In some embodiments, the influence of a shading signal

$${S}_{PSD} ( {B}_{1}^{+} ( \vec{r} ) )$$

on an image signal is typically in a trigonometric function relationship. The trigonometric function may be any form of trigonometric function, such as a sine function, a cosine function, a tangent function, etc., which will not be illustrated one by one here. The shading signal

$${S}_{PSD} ( {B}_{1}^{+} ( \vec{r} ) )$$

may be influenced by the scan sequence PSD (e.g., parameters such as repetition time, flip angle, and echo time) used, and the radio-frequency transmitting field

$${B}_{1}^{+} ( \vec{r} ) ,$$

and the sensitivity of the shading signal may be influenced by parameters of an imaged tissue (e.g., longitudinal relaxation time T1, and transverse relaxation time T2). Hence, the shading signal

$${S}_{PSD} ( {B}_{1}^{+} ( \vec{r} ) )$$

is, in a preset scan sequence, a function whose variables are the subject (different tissues have different longitudinal relaxation time T1 and transverse relaxation time T2) and the flip angle, and can be regarded as a spatial signal distribution value caused by the field intensity distribution of the radio-frequency transmitting field.

For example, the shading signal

$${{S}_{PSD} ( {B}_{1}^{+} ( \vec{r} ) )}^{estimate}$$

may be estimated using the following Formula (3):

$${{S}_{PSD} ( {B}_{1}^{+} ( \vec{r} ) )}^{estimate} = {C}_{1} \times f ( θ ) + {C}_{2} \times {f ( ( θ ) )}^{2} + … + {C}_{n} \times {f ( ( θ ) )}^{n} \qquad Formula ( 3 )$$

where, θ is an angle value in the angle map, ƒ(θ) may be a sine function value, C₁ to Cₙ is a weight parameter greater than 0, which may be any value between 0 and 1, or may be a value greater than or equal to 1. n is the number of times for which the trigonometric function value is adjusted based on the weight parameter. n is greater than 0, and may be an integer or decimal. For example, n may be 1 or 2, or a number between 0 and 2. The above-described weight parameter may be an empirical value, which may be embedded in a magnetic resonance system after being verified in many ways. For example, in one example, by substituting a suitable empirical value into Formula (3), it can be obtained that

$${{S}_{PSD} ( {B}_{1}^{+} ( \vec{r} ) )}^{estimate} \approx {sin ( \frac{π}{2} {B}_{map} )}^{power} .$$

This is only for illustration, and embodiments of the present application are not limited thereto. As previously described, upon normalizing the radio-frequency field map

$${{B}_{1} ( \vec{r} )}^{estimate} ,$$

Bₘₐₚ is obtained. The value of power is related to the second scan sequence, and may also be adjusted empirically and predetermined by a magnetic resonance system. For example, when the excitation pulse is 90° and the refocusing pulse is 180°, power=3. This is only for illustration, and embodiments of the present application are not limited thereto. Upon determining Bₘₐₚ and power, the shading signal

$${{S}_{PSD} ( {B}_{1}^{+} ( \vec{r} ) )}^{estimate}$$

can be obtained. The shading signal

$${{S}_{PSD} ( {B}_{1}^{+} ( \vec{r} ) )}^{estimate}$$

may then serve as a trigonometric function value of the angle map.

In some embodiments, in 403, when the correction factor P is determined based on

$$\frac{{S}_{body} ( \vec{r} )}{{S}_{surface} ( \vec{r} )} ,$$

the update the correction factor based on a trigonometric function value of the angle map and the radio-frequency field map comprises: dividing the correction factor by the trigonometric function value and the radio-frequency field map to obtain an updated correction factor. For example, the updated correction factor P′ may be obtained by the following Formula (4):

$$P ’ = \frac{P}{{{S}_{PSD} ( {B}_{1}^{+} ( \vec{r} ) )}^{estimate} {{B}_{1} ( \vec{r} )}^{estimate}} \qquad Formula ( 4 )$$

In some embodiments, in 403, when the correction factor P is determined based on

$$\frac{HF ( {S}_{body} ( \vec{r} ) )}{{S}_{surface} ( \vec{r} )} ,$$

the update the correction factor based on a trigonometric function value of the angle map and the radio-frequency field map comprises: multiplying, by the radio-frequency field map, the correction factor divided by the trigonometric function value to obtain an updated correction factor. For example, the updated correction factor P′ may be obtained by the following Formula (5):

$$P ’ = \frac{{{PB}_{1} ( \vec{r} )}^{estimate}}{{{S}_{PSD} ( {B}_{1}^{+} ( \vec{r} ) )}^{estimate}} \qquad Formula ( 5 )$$

In some embodiments, with regard to the updated correction factor P′, since it is calculated from the low-resolution image data, in order to correct high-resolution image data (scanned image data), P′ can be further subjected to resolution adjustment (reformat). In 304, the correction factor P″ after the resolution adjustment is multiplied by the scanned image data to correct the scanned image data to obtain the corrected scanned image data.

In some embodiments, if a next subject is to receive scanning, then the above-described imaging method will be performed again.

The principle of correcting the scanned image data using the above Formulas (1) to (5) will be described below.

In embodiments of the present application, correction of the scanned image data

$$S ( \vec{r} )$$

with the following Formula (6) affords a first corrected image

$${I}_{1} ( \vec{r} ) .$$

$${I}_{1} ( \vec{r} ) = S ( \vec{r} ) \frac{{S}_{body} ( \vec{r} )}{{S}_{surface} ( \vec{r} )} = {S}_{PSD} ( {B}_{1}^{+} ( \vec{r} ) ) {B}_{1 s}^{-} ( \vec{r} ) \frac{ρ ( \vec{r} ) {B}_{1}^{+} ( \vec{r} ) {B}_{1}^{-} ( \vec{r} )}{ρ ( \vec{r} ) {B}_{1}^{+} ( \vec{r} ) {B}_{1 s}^{-} ( \vec{r} )} = {S}_{PSD} ( {B}_{1}^{+} ( \vec{r} ) ) {B}_{1}^{-} ( \vec{r} ) \qquad Formula ( 6 )$$

If the correction is performed using the principle of Formula (6), the initial correction factor is determined based on the ratio of the first image data to the third image data.

$$Collected image data = ideal signal \times {S}_{PSD} ( {B}_{1}^{+} ( \vec{r} ) ) {B}_{1}^{-} ( \vec{r} ) . If {S}_{PSD} ( {B}_{1}^{+} ( \vec{r} ) ) {B}_{1}^{-} ( \vec{r} )$$

can be estimated, then dividing the collected image data by

$${S}_{PSD} ( {B}_{1}^{+} ( \vec{r} ) ) {B}_{1}^{-} ( \vec{r} )$$

can eliminate an excess signal to obtain the ideal signal, thereby completing correction. In this regard, the product of the above-described estimated shading signal

$${{S}_{PSD} ( {B}_{1}^{+} ( \vec{r} ) )}^{estimate}$$

and the radio-frequency field map

$${{B}_{1} ( \vec{r} )}^{estimate}$$

may be regarded as

$${S}_{PSD} ( {B}_{1}^{+} ( \vec{r} ) ) {B}_{1}^{-} ( \vec{r} ) .$$

In some embodiments, correction may also be performed with the following Formula (7) to obtain a second corrected image

$${I}_{2} ( \vec{r} ) .$$

$${I}_{2} ( \vec{r} ) = S ( \vec{r} ) \frac{HF ( {S}_{body} ( \vec{r} ) )}{{S}_{surface} ( \vec{r} )} = {S}_{PSD} ( {B}_{1}^{+} ( \vec{r} ) ) {B}_{1 s}^{-} ( \vec{r} ) \frac{ρ ( \vec{r} )}{ρ ( \vec{r} ) {B}_{1}^{+} ( \vec{r} ) {B}_{1 s}^{-} ( \vec{r} )} = \frac{{S}_{PSD} ( {B}_{1}^{+} ( \vec{r} ) )}{{B}_{1}^{+} ( \vec{r} )} \qquad Formula ( 7 )$$

If the correction is performed using the principle of Formula (7), the initial correction factor is determined based on the ratio of the second image data to the third image data.

$$Collected image data = ideal signal \times \frac{{S}_{PSD} ( {B}_{1}^{+} ( \vec{r} ) )}{{B}_{1}^{+} ( \vec{r} )} .$$

### If

$$\frac{{S}_{PSD} ( {B}_{1}^{+} ( \vec{r} ) )}{{B}_{1}^{+} ( \vec{r} )}$$

can be estimated, then dividing the collected image data by

$$\frac{{S}_{PSD} ( {B}_{1}^{+} ( \vec{r} ) )}{{B}_{1}^{+} ( \vec{r} )}$$

can eliminate an excess signal to obtain the ideal signal, thereby completing correction. In this regard, the ratio of the above-described estimated shading signal

$${{S}_{PSD} ( {B}_{1}^{+} ( \vec{r} ) )}^{estimate}$$

to the radio-frequency field map

$${{B}_{1} ( \vec{r} )}^{estimate}$$

may be regarded as

$$\frac{{S}_{PSD} ( {B}_{1}^{+} ( \vec{r} ) )}{{B}_{1}^{+} ( \vec{r} )} .$$

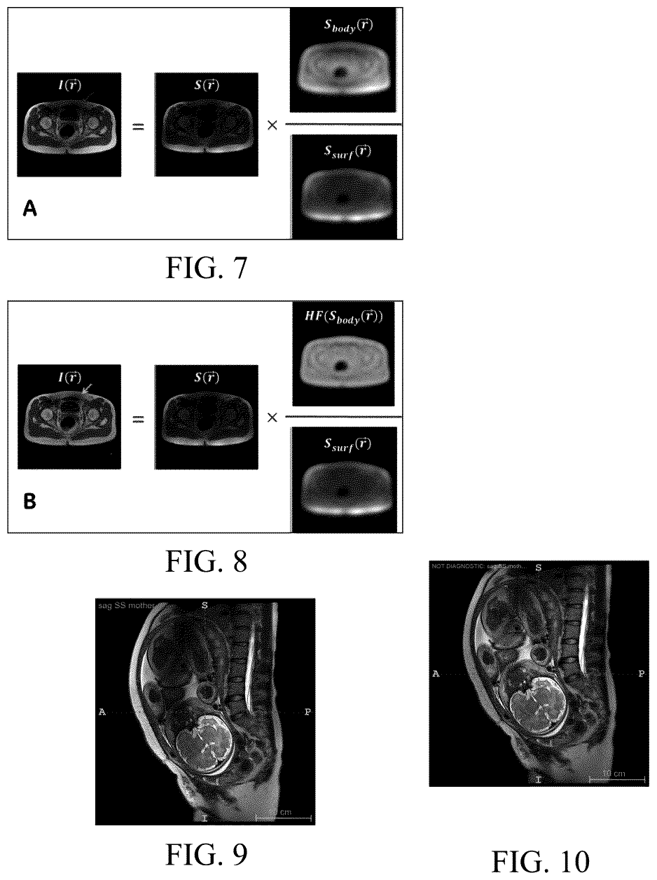

With the above formulas in conjunction with FIG. 7 and FIG. 8, and assuming that the shading signal of the second coil during the pre-scan is consistent with the shading signal thereof during the formal scan, the non-uniform radio-frequency receiving field

$${B}_{1 s}^{-} ( \vec{r} )$$

of the second coil (surface coil) in the scanned image data can be eliminated by calculating

$$\frac{S ( \vec{r} )}{{S}_{surface} ( \vec{r} )} .$$

FIG. 9 is a schematic diagram of a scanned image obtained using a conventional image method, and FIG. 10 is a schematic diagram of a scanned image corrected using the magnetic resonance imaging method of embodiments of the present application. As shown in FIG. 9 and FIG. 10, the method can reduce a dielectric shading as much as possible, compensate for the missing signal and contrast in the image, and enhance the uniformity and consistency of the image.

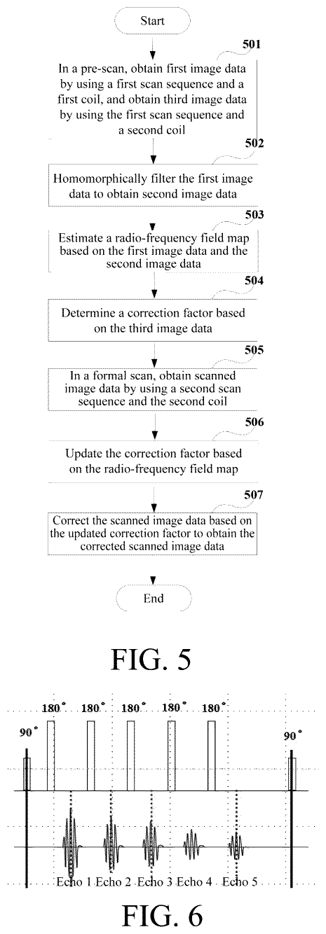

FIG. 5 is a flowchart of a magnetic resonance imaging method according to embodiments of the present application. As shown in FIG. 5, the method comprises the following steps. First, in 501, a pre-scan is performed to obtain first image data using a first scan sequence and a first coil, and third image data is obtained using the first scan sequence and a second coil. Next, in 502, the first image data is homomorphically filtered to obtain second image data, and in 503, a radio-frequency field map is estimated based on the first image data and the second image data. Then, in 504, a correction factor is determined based on the third image data. In 505, a formal scan is performed to obtain scanned image data using a second scan sequence and the second coil. Finally, steps 506 and 507 involve updating the correction factor based on the radio-frequency field map and correcting the scanned image data based on the updated correction factor to obtain the corrected scan image data.

Specific implementations of 501 to 507 are as previously described and will not be repeated here.

It should be noted that, in embodiments of the present application, the radio-frequency field map in 503 can also be obtained not by estimating based on the first image data and the second image data, but by simulating the receiving coil by using a designed scan sequence or by performing scanning by using B₁ map fast collection sequence, and can be previously stored in a magnetic resonance system. Reference can be made to relevant technologies for specific simulation methods, and embodiments of the present application are not limited thereto.

In addition, the above Formula (2) is used as an example to describe how to estimate the radio-frequency field map

$${B}_{1} ( \vec{r} )$$

based on the first image data and the second image data, but embodiments of the present application are not limited thereto. For example, the first corrected image

$${I}_{1} ( \vec{r} )$$

may also be obtained based on the first image data, the third image data and the scanned image data in conjunction with Formula (6), the second corrected image

$${I}_{2} ( \vec{r} )$$

may be obtained based on the second image data, the third image data and the scanned image data in conjunction with Formula (7), and the radio-frequency field map

$${B}_{1} ( \vec{r} )$$

may be estimated based on Formula (8). Embodiments of the present application are not limited thereto.

$${{B}_{1} ( \vec{r} )}^{estimate} \approx \sqrt{{B}_{1}^{+} ( \vec{r} ) {B}_{1}^{-} ( \vec{r} )} = \sqrt{\frac{{I}_{1} ( \vec{r} )}{{I}_{2} ( \vec{r} )}} \qquad Formula ( 8 )$$

It should be noted that the above image data (e.g., the first image data and the third image data) may be original image data, or may be image data obtained after preprocessing the original image data. The preprocessing includes, but is not limited to, normalization processing, low-pass filtering processing, regularization processing, etc. The embodiments of the present application are not limited thereto.

It should be noted that the above figures merely schematically illustrate the embodiments of the present application, but the present application is not limited thereto. For example, the order of execution between operations may be appropriately adjusted. In addition, some other operations may be added or some operations may be omitted. Those skilled in the art can make appropriate variations according to the above content, rather than being limited by the disclosure of the foregoing accompanying drawings.

The above embodiments merely provide illustrative descriptions of the embodiments of the present application. However, the present application is not limited thereto, and suitable variations may be made on the basis of the above embodiments. For example, each of the above embodiments may be used independently, or one or more of the above embodiments may be combined.

In the foregoing embodiments, through obtaining first image data by using a first scan sequence; filtering the first image data to obtain second image data; estimating a radio-frequency field map based on the first image data and the second image data, and correcting the scanned image data based on the estimated radio-frequency field map, the dielectric shading in the image can be reduced as much as possible, the missing signal and contrast in the image can be compensated for, the uniformity and consistency of the image can be enhanced, the quality of the image can be improved, and the confidence of diagnosis can be increased.

Embodiments of the present application further provide a method for determining a radio-frequency field map, the method comprising: obtaining first image data by using a first scan sequence; filtering the first image data to obtain second image data; estimating a radio-frequency field map based on the first image data and the second image data. For the implementations of the method, reference can be made to the foregoing embodiments, which will not be repeated here. The estimated radio-frequency field map may be used for other scenarios in addition to being used for correcting the scanned image data, and embodiments of the present application are not limited thereto.

Embodiments of the present application further provide a magnetic resonance imaging system. The configuration of the magnetic resonance imaging system is as shown in FIG. 1, and what are the same will not be repeated here.

In some embodiments, what differs from the foregoing magnetic resonance imaging system in FIG. 1 is that the controller 130 is configured to perform the foregoing magnetic resonance imaging method.

In some embodiments, the controller 130 (which may also be a processor) comprises a computer processor and a storage medium. The storage medium has recorded thereon a predetermined data processing program to be executed by the computer processor. For example, the storage medium may store a program configured to implement scanning processing (for example, including waveform design/conversion, and the like), image reconstruction, image processing, etc. For example, the storage medium may store a method configured to determine a radio-frequency field map according to embodiments of the present application. The specific implementation thereof is as described above, and will not be repeated here.

The above storage medium may include, for example, a ROM, a floppy disk, a hard disk, an optical disk, a magneto-optical disk, a CD-ROM, or a non-volatile memory card.

The embodiments of the present application further provide a computer-readable program. When the program is executed in an apparatus or an MRI system, the program enables a computer to perform, in the apparatus or the MRI system, the method according to the foregoing embodiments.

Embodiments of the present application further provide a storage medium having a computer-readable program stored thereon. The computer-readable program causes a computer to perform the method according to the foregoing embodiments in an apparatus or MRI system.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A magnetic resonance imaging method, characterized by comprising:
obtaining first image data by using a first scan sequence;
filtering the first image data to obtain second image data;
estimating a radio-frequency field map based on the first image data and the second image data; and
obtaining scanned image data by using a second scan sequence, and correcting the scanned image data based on the estimated radio-frequency field map to obtain the corrected scanned image data.

2. The method according to claim 1, wherein the first scan sequence comprises a spoiled gradient recalled echo sequence, and the second scan sequence comprises a spin echo sequence.

3. The method according to claim 1, wherein the filtering comprises homomorphic filtering.

4. The method according to claim 1, wherein the estimating a radio-frequency field map based on the first image data and the second image data comprises: determining the radio-frequency field map based on the ratio of the first image data to the second image data.

5. The method according to claim 4, wherein the radio-frequency field map is determined based on an arithmetic square root of the ratio of the first image data to the second image data.

6. The method according to claim 1, wherein the correcting the scanned image data based on the estimated radio-frequency field map to obtain the corrected scanned image data comprises:
obtaining third image data by using the first scan sequence;
determining a correction factor based on the third image data;
updating the correction factor based on the estimated radio-frequency field map; and
correcting the scanned image data based on the correction factor to obtain the corrected scanned image data.

7. The method according to claim 6, wherein the first image data is obtained by using a first coil, and the third image data and the scanned image data are obtained by using a second coil.

8. The method according to claim 7, wherein the first coil comprises a body coil, and the second coil comprises a surface coil.

9. The method according to claim 6, wherein the updating the correction factor based on the estimated radio-frequency field map comprises:
determining a central angle;
converting the radio-frequency field map into an angle map based on the central angle; and
updating the correction factor based on a trigonometric function value of the angle map and the radio-frequency field map.

10. The method according to claim 9, wherein the updating the correction factor based on a trigonometric function value of the angle map and the radio-frequency field map comprises: dividing the correction factor by the trigonometric function value and the radio-frequency field map to obtain an updated correction factor, or multiplying, by the radio-frequency field map, the correction factor divided by the trigonometric function value to obtain an updated correction factor.

11. The method according to claim 6, wherein the first image data and the third image data are low-resolution proton density weighted image data.

12. The method according to claim 6, wherein the determining a correction factor based on the third image data comprises:
determining the correction factor based on the third image data and the first image data; or,
determining the correction factor based on the third image data and the second image data.

13. The method according to claim 12, wherein
the determining the correction factor based on the third image data and the first image data comprises: determining the correction factor based on the ratio of the first image data to the third image data; and
the determining the correction factor based on the third image data and the second image data comprises: determining the correction factor based on the ratio of the second image data to the third image data.

14. The method according to claim 12, wherein when the correction factor is determined based on the ratio of the first image data to the third image data, the correction factor is divided by a trigonometric function value and the radio-frequency field map to obtain an updated correction factor; or when the correction factor is determined based on the ratio of the second image data to the third image data, the correction factor is divided by a trigonometric function value and multiplied by the radio-frequency field map to obtain an updated correction factor.

15. The method according to claim 1, comprising:
performing a pre-scan, wherein the first image data is obtained by using the first scan sequence; and
performing a formal scan, wherein the scanned image data is obtained by using the second scan sequence.

16. The method according to claim 6, comprising:
performing a pre-scan, wherein the first image data and the third image data are obtained by using the first scan sequence; and
performing a formal scan, wherein the scanned image data is obtained by using the second scan sequence.

17. A magnetic resonance imaging system, characterized by comprising:
a scanning unit; and
a controller, configured to perform the magnetic resonance imaging method according to claim 1.
